(19) United States
(12) Patent Application Publication
(10) Pub. No.: US 2026/0271411 A1
(43) Pub. Date: Sep. 10, 2026

(54) FERROELECTRIC III-NITRIDE ALLOY-BASED PHOTODETECTORS

(71) Applicant: The Regents of the University of Michigan, Ann Arbor, MI (US)

(72) Inventors: Shubham Mondal, Ann Arbor, MI (US); Ding Wang, Beijing (CN); Ping Wang, Beijing (CN); Zetian Mi, Ann Arbor, MI (US)

(21) Appl. No.: 19/131,905

(22) PCT Filed: Nov. 22, 2023
(86) PCT No.: PCT/US2023/080836

§ 371 Date: May 21, 2025

Related U.S. Application Data
(60) Provisional application No. 63/427,336, filed on Nov. 22, 2022.

(51) Int. Cl. H10F 30/227; H10F 71/00; H10F 77/124; H10F 77/20

(52) U.S. Cl. CPC H10F 30/2275; H10F 71/1274; H10F 77/12485; H10F 71/138; H10F 77/254

(57) ABSTRACT

An optoelectronic device includes a first electrode, a ferroelectric semiconductor layer supported by the first electrode, and a second electrode supported by the ferroelectric semiconductor layer, the second electrode being configured to allow the ferroelectric semiconductor layer to be illuminated. The ferroelectric semiconductor layer comprises a III-nitride alloy, the III-nitride alloy including a group IIIB element.

### CROSS-REFERENCE TO RELATED APPLICATION

This application claims the benefit of U.S. provisional application entitled “Ferroelectric III-Nitride Alloy-Based Photodetectors,” filed Nov. 22, 2022, and assigned Ser. No. 63/427,336, the entire disclosure of which is hereby expressly incorporated by reference.

### BACKGROUND OF THE DISCLOSURE

### Field of the Disclosure

The disclosure relates generally to ferroelectric photodetectors.

### Brief Description of Related Technology

The increasing demand for sustainable and energy efficient technology has propelled scientific research towards the realization of self-powered photovoltaic (PV) devices for, e.g., solar energy scavenging and photo detection. In recent years, ultraviolet (UV) photodetection has emerged as a technology useful in a number of applications, including missile tracking, biological and chemical analysis, Internet of Things (IOT) sensors, and environmental monitoring. Traditionally, such UV photodetectors have been mostly based on ZnO, TiO₂, SnO₂, and ZnS, which rely on an external bias to drive the separation and transport of photogenerated charge carriers. However, dependency on an external power source for operation increases the size of the packaged devices and renders the devices incompatible for several in-situ applications.

Extensive research to circumvent the external power source problem led to the development of photovoltaic photodetectors—devices that could be effectively operated without any external driver. Among the proposed mechanisms for self-powered operation, ferroelectric photovoltaics have been of interest due to an amalgamation of properties such as large spontaneous and piezoelectric polarization fields, polarization dependent photocurrent, and above bandgap photovoltage. When a poled ferroelectric material is illuminated with an appropriate wavelength of light, the internal depolarization field separates the photo-induced e-h pairs, giving rise to short-circuit current in the direction of the ferroelectric polarization axis. This unique property of ferroelectric materials bypasses the need to have a semiconductor junction for carrier separation. Moreover, ferroelectric materials possess an inherent unit-cell originating spontaneous polarization, the spatial direction of which can be altered between two stable states. This functionality offers further control and reconfigurability of the photovoltaic response of these photodetectors.

Such self-powered ferroelectric photodetectors being investigated today are primarily based on perovskite materials like BaTiO₃, BiFeO₃, and Pb(Zr, Ti)O₃. Even though such perovskites have emerged to be excellent photosensitive semiconductors, their application in the field of UV photodetection faces some serious challenges. Owing to solution processing techniques, such materials are prone to defects. As a result, such photodetectors suffer from recombination losses, larger leakage/dark currents, and scalability issues. Furthermore, their relatively narrow bandgap renders them incompatible for solar blind UV photodetection. Considerable efforts are under way for alleviating this issue, however, such approaches may result in a degraded intrinsic polarization field leading to poor electron-hole (e-h) pair separation and hence lower photoresponsivity. Chemical vapor deposition (CVD) allows for the deposition of uniform thin films onto large substrate sizes, which aids in the scalability of the perovskite deposition process. However, there remain persistent challenges and unresolved issues regarding their stability with UV light exposure, moisture, temperature, and toxicity, which limit their compatibility with existing platforms.

### SUMMARY OF THE DISCLOSURE

In accordance with one aspect of the disclosure, an optoelectronic device includes a first electrode, a ferroelectric semiconductor layer supported by the first electrode, and a second electrode supported by the ferroelectric semiconductor layer, the second electrode being configured to allow the ferroelectric semiconductor layer to be illuminated. The ferroelectric semiconductor layer includes a III-nitride alloy, the III-nitride alloy including a group IIIB element.

In accordance with another aspect of the disclosure, a method of fabricating an optoelectronic device includes providing a first electrode, implementing a non-sputtered, epitaxial growth procedure to form a ferroelectric semiconductor layer supported by the first electrode, and depositing a second electrode across the ferroelectric semiconductor layer, the second electrode being configured to allow the ferroelectric semiconductor layer to be illuminated. The ferroelectric semiconductor layer includes a III-nitride alloy, the III-nitride alloy including a group IIIB element.

In connection with any one of the aforementioned aspects, the devices and/or methods described herein may alternatively or additionally include or involve any combination of one or more of the following aspects or features. The III-nitride alloy has a bandgap sufficiently wide such that the optoelectronic device is solar-blind. The III-nitride alloy has a bandgap that corresponds with an ultraviolet C (UV-C) wavelength. The ferroelectric semiconductor layer is in contact with the first electrode. An interface between the first electrode and the ferroelectric semiconductor layer is buffer-free. The ferroelectric semiconductor layer exhibits uniform polarity. The first electrode includes molybdenum. The first electrode includes a bulk metal. The first electrode includes a semiconductor substrate. The first electrode includes a substrate and a metal layer supported by the substrate. The group IIIB element is scandium. The III-nitride alloy is ScAlN. The non-sputtered, epitaxial growth procedure is implemented in N-rich conditions. Providing the first electrode includes forming a metal layer on a substrate. The metal layer includes molybdenum. Forming the metal layer includes removing an oxide from a surface of the metal layer. Forming the metal layer includes annealing the metal layer in a vacuum to remove an oxide from a surface of the metal layer. The first electrode includes a bulk metal. The first electrode includes a semiconductor substrate. Implementing the non-sputtered, epitaxial growth procedure includes growing the ferroelectric semiconductor layer on the first electrode such that an interface between the first electrode and the ferroelectric semiconductor layer is buffer-free. The method further includes annealing the ferroelectric semiconductor layer.

### BRIEF DESCRIPTION OF THE DRAWING FIGURES

For a more complete understanding of the disclosure, reference should be made to the following detailed description and accompanying drawing figures, in which like reference numerals identify like elements in the figures.

FIG. 1 depicts (a) a cross-sectional SEM image and (b) HAADF-STEM images of example ScAlN/Mo heterostructures grown by MBE, (c) a graphical plot of a XRD 2θ-ω scan for the ScAlN/Mo heterostructure, (d) graphical plots of J-E and corresponding P-E loops measured at 10 KHz from an example Au/Ti/ScAlN/Mo structure, showing clear ferroelectric polarization switching, with the arrows denoting the switching current.

FIG. 2 depicts (a) a schematic representation of an example device heterostructure grown by MBE with the enlarged portion (on the left) showing a cross-sectional view, (b) an optical photograph showing the top and bottom electrodes of an example device, graphical plots of (c) J-V and (d) J-t characteristics of the device with and without illumination at V=0V showing the polarization dependent open circuit voltage (V_{oc}) and short circuit current density (J_{sc}) in three states along with the dark current density, with the J-t characteristic curves having been smoothed two points to increase readability.

FIG. 3 depicts energy band diagrams of the ferroelectric ScAlN layer under illumination at zero bias showing the schematic representation of the photo-generation and separation of e-h pairs in the three states—(a) as-grown, (b) pole down and (c) pole up. The arrow marked “P” denotes the polarization direction in the material, “E_{d}” denotes the corresponding depolarization field and “E_{b}” denotes the built-in electric field at the ScAlN/Ni interface. The band diagram and carrier transport mechanism in the (a) as-grown and (b) pole-down state suggests that the net electric field at the ScAlN/Ni interface, Eᵢₙₜ=E_{d}+E_{b}, whereas for the (c) pole-up state E_{b} opposes E_{d} owing to the reorientation of polarization, hence Eᵢₙₜ=E_{d} E_{b} (|E_{d}|>|E_{b}|). The dashed red (light) and black (dark) lines schematically illustrate the quasi-Fermi levels in ScAlN, assuming uniform illumination and neglecting carrier recombination.

FIG. 4 depicts graphical plots of pulsed photocurrent measurements showing the influence of illumination intensity on the observed short-circuit photocurrent response of the material for the (a) as-grown, (b) pole-down, and (c) pole-up state, (d) power-law fitting of the light power density dependence for the three cases, (e) stability of the photocurrent response under ambient conditions, and (f) rise and fall times of the three states.

FIG. 5 depicts graphical plots of illumination density dependent Responsivity (Rₚ) and Detectivity (D*) results extracted from the pulsed photocurrent measurements for the (a) as-grown, (b) pole-down, and (c) pole-up states.

FIG. 6 is a flow diagram of a method of fabricating an optoelectronic device in accordance with one example.

The embodiments of the disclosed devices and methods may assume various forms. Specific embodiments are illustrated in the drawing and hereafter described with the understanding that the disclosure is intended to be illustrative. The disclosure is not intended to limit the invention to the specific embodiments described and illustrated herein.

### DETAILED DESCRIPTION OF THE DISCLOSURE

Photodetector devices based on ferroelectric III-nitride alloys, such as ScAlN, are described. The ferroelectric III-nitride alloy may have a bandgap (e.g., an ultrawide bandgap) useful for deep UV detection. The ferroelectric nature of the III-nitride alloy allows the photodetectors to be reconfigurable and self-powered. Methods for fabricating such photodetector devices are also described.

III-nitride materials are a useful platform for high performance UV-optoelectronic device applications. Polarization switching in Sc-alloyed III-nitride materials has initiated a huge surge in interest in nitride-based ferroelectric applications, a functionality which to date was elusive for the III-nitride semiconductor family. Sc-based III-nitride alloys exhibit large tunable coercive fields (1.6-5 MVcm⁻¹), wide direct-bandgap (4.9-5.6 eV), remarkable switchable polarization (80-120 μC/cm²), and high temperature phase stability (1100° C.), making the alloys suitable for a wide range of piezoelectric and ferroelectric applications. Moreover, the alloys possess an edge over the conventional perovskite ferroelectrics as the alloys exhibit robust ferroelectric behavior under harsh environments.

While the focus has been primarily on the demonstration of ferroelectric nitride memories and some transistor applications, the unique properties of the III-nitride alloys are useful beyond the current niche of applications. While some initial studies have illustrated the optical characteristics of ScAlN, to date there has been no report on ScAlN-based optoelectronic devices. The robust ferroelectric property of ScAlN, with its direct wide-band gap along with large inherent polarization fields, is useful for photodetector applications, including, for instance, in the field of self-powered deep UV photodetection.

Described herein are examples of III-nitride alloy-based solar-blind self-powered ferroelectric photodetector devices operating in the deep UV spectral region. For example, ScAlN films used for the photodetectors were directly grown on Molybdenum (Mo)/Si (111) templates using plasma-assisted Molecular Beam Epitaxy (MBE). Epitaxially grown III-N heterostructures on Mo provide a viable path to achieve CMOS compatible ferroelectric nitrides, such as for large scale production and integration with other functional circuits and devices. Examples of Ni/ScAlN/Mo self-powered photodetectors were found to demonstrate polarization dependent photocurrent upon illumination (λ=193 nm). The highest recorded responsivity and detectivity of the devices reached a Rₚ of about 15 mA/W and a D* of about 1.2×10¹¹ Jones, respectively. The response speed (τᵣᵢₛₑ/τ_{fall}) is less than 0.06 s and stable photocurrent is observed for a duration of more than 60 days for a device without any packaging.

The results obtained by the examples are addressed with energy band diagrams, which establish the role of the depolarization field in the separation and transport of photo-generated carriers to attain reconfigurable photo response in these devices. Overall, the results presented herein establish the realization of III-nitride based high performance ferroelectric photovoltaic devices on various semiconductor platforms.

Although described in connection with examples of epitaxially grown ScAlN layers, the disclosed methods and devices may be applied to a wide variety of III-nitride alloys. The disclosed methods and devices may thus include or involve the incorporation of scandium into other III-nitride wurtzite structures. For instance, the disclosed methods and devices may include or involve one or more epitaxially grown ScₓAl_{y}Ga_{1-x-y}N layers, ScₓGa₁₋ₓN layers, or ScₓIn₁₋ₓN layers. The configuration, construction, fabrication, and other characteristics of the heterostructures may also vary from the examples described. For instance, the heterostructures may include any number of epitaxially grown layers of ferroelectric and non-ferroelectric nature. The disclosed methods and devices are not limited to III-nitride alloys including scandium. For instance, the III-nitride alloys may include additional or alternative group IIIB elements, such as yttrium (Y) and lanthanum (La).

Although the disclosed methods are described in connection with MBE growth procedures, additional or alternative non-sputtered epitaxial growth procedures may be used. For instance, metal-organic chemical vapor deposition (MOCVD), hydride vapor phase epitaxy (HVPE), atomic layer deposition (ALD), and atomic layer epitaxy (ALE) growth procedures may be used. Still other procedures may be used, including, for instance, pulsed laser deposition procedures.

Example ScAlN films were grown on a Mo template utilizing a Veeco Genxplor MBE system equipped with a radio-frequency nitrogen plasma source to provide active nitrogen atoms, and Knudsen effusion cells for Sc and Al sources. The ScAlN films were grown under N-rich conditions to avoid intermetallic and perovskite phase formation. The purity of the Sc source is 99.999%. Based on a SIMS calibration, the ScAlN films had a Sc content of about 0.2 and an UID oxygen concentration of about 4×10¹⁸ cm⁻³, although other content and concentration levels may be used or present in other cases.

Further details on the epitaxial growth conditions and other aspects of the ferroelectric layers and heterostructures described herein may be found in the following publications, the entire disclosures of which are hereby incorporated by reference:
Wang, et al., Advanced Electronic Materials, 2200005 (2022);
Wang, et al., Applied Physics Letters 118 (22), 223504 (2021);
Wang, et al., Appl. Phys. Lett. 121, 042108 (2022);
U.S. Patent Application No. 63/408,341 (“Heterostructures with Ferroelectric III-Nitride Layer on Metal”);
U.S. Patent Application No. 63/313,002 (“Epitaxial Nitride Ferroelectronic Devices”); and International Application No. PCT/US2022/028365 (“Epitaxial Nitride Ferroelectronics”).

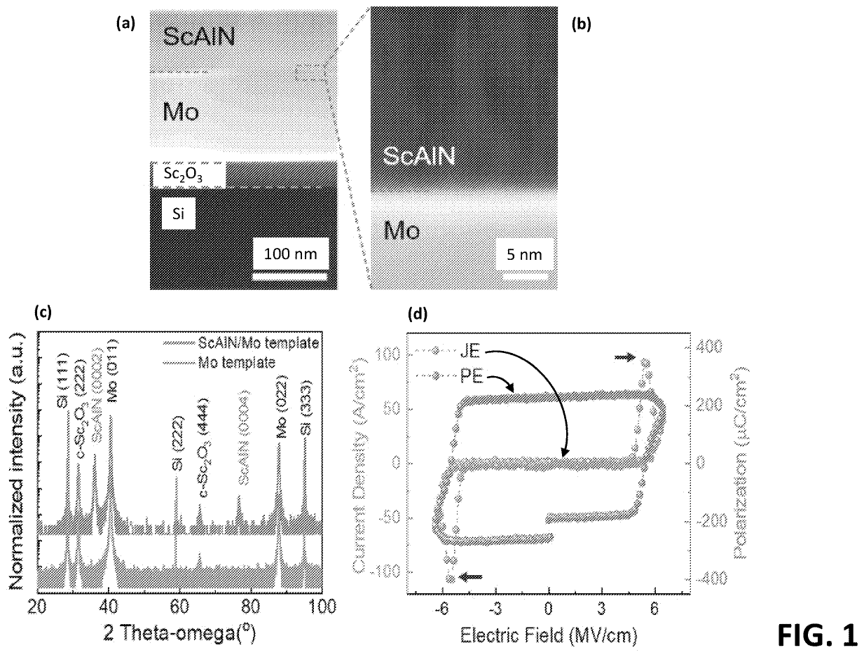

FIG. 1, part (a), shows the cross-section scanning electron microscopy (SEM) image of the example ScAlN film directly grown on a Mo/Si (111) template without using any buffer layer. The ScAlN layer has a thickness of about 100 nm with a Sc content of about 20%. Other thicknesses may be used. FIG. 1, part (b), shows a high angle annular dark field scanning transmission electron microscope (HAADF-STEM) image, showing an atomically sharp ScAlN/Mo interface achieved by epitaxial growth. XRD 2theta-omega (2θ-ω) scans for the ScAlN/Mo heterostructure were carried out with a Cu Kα radiation X-ray source (1.54 Å) and are plotted in FIG. 1, part (c). The wurtzite crystal structure for the epitaxially grown ScAlN was confirmed by the characteristic diffraction peak at about 36°. Compared to the Mo template, no other diffraction peaks were observed for ScAlN in the long-range scan (20-100°) except for the diffraction peaks from the (0002) family of crystal planes. This is a useful aspect of the epitaxially grown ScAlN films compared to sputtered films, in which multiple domains with different orientations co-exist in the ScAlN/Mo films. As a result, robust ferroelectricity can be achieved in the MBE-grown ScAlN of the example heterostructure. The ferroelectric switching behavior was characterized using a Radiant Precision Multiferroic II Ferroelectric Test system driven from the top electrode. FIG. 1, part (d), shows the J-E and the corresponding P-E loops measured from a Ni/ScAlN/Mo capacitor with a top electrode diameter of 20 μm. The displacement current and saturated polarization confirm the presence of ferroelectricity in the example ScAlN film.

A dielectric stack having 200 nm SiO₂ was deposited using a Plasma Enhanced Chemical Vapor Deposition (PECVD) system, followed by Atomic Layer Deposition (ALD) of 40 nm HfO₂ on the epitaxially grown samples. The components, composition, thicknesses, and/or other characteristics of the dielectric stack may vary. For instance, one or more additional dielectric layers may be included in the stack. In this case, HfO₂ acts as a deep UV blocking layer and hence defines the active area under illumination. Single step photolithography was performed followed by plasma etching to create openings on the dielectric stack. An additional step of photolithography followed by Reactive Ion Etching (RIE) was done to make openings in the ScAlN layer for Ohmic metal deposition. Next, contacts including Ti/Au layers were deposited (which were later used as probing pads), thereby defining the active area of the device as well. An ultra-thin layer of Ni (about 5 nm) is deposited to cover the active area, which serves as a UV-semitransparent layer.

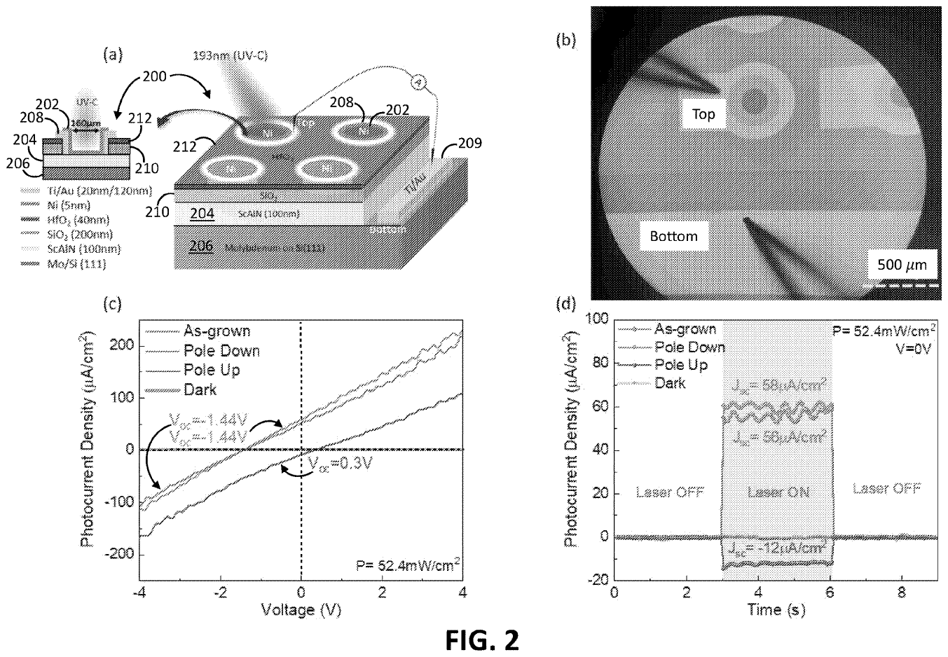

FIG. 2, part (a), shows a schematic of an example ScAlN based photodetector 200 with an enlarged sectional view of the top contact region being illuminated. In this example, a highly conductive, ultra-thin Nickel layer (about 5 nm) is used as a UV-semitransparent (with a transmittance of about 64%) top electrode 202 on a ScAlN layer 204. An underlying Molybdenum layer is used as a bottom electrode 206, while overlapping Ti/Au layers serve as contact pads 208, 209. Additional or alternative metals may be used in other cases. The device 200 also includes a dielectric stack having an SiO₂ layer 210 and a UV-blocking (e.g., HfO₂) layer 212, as described above. The thicknesses and/or other characteristics of the contacts, dielectric stack, and electrodes may vary.

FIG. 2, part (b), shows the photograph of an actual device being probed for photocurrent density measurements. To exploit the polarization dependent photosensitivity of the ferroelectric material, a poling pulse of magnitude ±45V and width 0.1 s was applied, resulting in a polarization dependent photovoltaic response. The “Pole Up” state corresponds to +45V being applied to the bottom electrode (Mo), whereas the “Pole Down” corresponds to −45V being applied to the bottom electrode. As the optical bandgap of Sc_{0.2}Al_{0.8}N was calculated to be 5.42 eV, accordingly, a 193 nm ArF excimer laser (hv=6.42 eV) was used for above bandgap illumination in the photovoltaic measurements. FIG. 2, part (c), and FIG. 2, part (d), show the polarization dependent current density (J) in the unpoled and poled states, respectively. In this case, J=I/S, where S=πr² is the effective area under illumination, and r equals 80 μm.

Under illumination, the photogenerated e-h pairs are separated by the inherent depolarization field present within the ferroelectric material, and subsequently collected and transferred to the electrodes and external circuitry. Thus, the direction of photocurrent depends on the polarization state of the ferroelectric ScAlN layer. The as-grown sample shows a positive photo response together with a negative open circuit voltage (V_{oc}=−1.44 V and J_{sc}=56 μA/cm²).

Usually, ferroelectrics suffer from an associated “wake-up” effect, i.e., the crystal domains need to be electrically initialized to have a uniform dipole orientation. As a result, the photocurrent in the poled state is generally higher than the as-grown state. To investigate the possible wake-up process in the example ferroelectric films, a “Pole Down” pulse was applied and the short-circuit photocurrent at zero bias was subsequently recorded. The direction and magnitude of the photocurrent remained similar to the unpoled state, (V_{oc}=−1.44 V and J_{sc}=58 μA/cm², shown in FIG. 2, part d), implying that the as-grown ScAlN layer on Mo is metal-polar. Even after repeated cycling, this observation remained consistent. This suggests that the as-grown ferroelectric films by MBE possess uniform polarity and do not require additional “wake-up” cycles.

As the disclosed photodetectors operate in a self-powered mode, i.e., without the application of any external bias, this wake-up free photo response renders a significant advantage compared to other ferroelectric photodetectors, in which a series of poling pulses are necessary for the devices to be functional.

As the device is “Poled Up” by applying an opposite bias, the short-circuit photocurrent reverses direction (V_{oc}=0.3 V and J_{sc}=−12 μA/cm²). This reversal of J_{sc} by a “writing” voltage is direct evidence of the presence of ferroelectric polarization in the material. Also, such a polarization dependent photo response confirms that the photo-induced carriers are generated primarily in the ferroelectric ScAlN layer. However, as shown in FIGS. 2, parts (c) and (d), compared to the as-grown and “Pole Down” state, a reduced photovoltaic response is observed in the “Pole Up” state, suggesting that there exists some hindrance to effective carrier collection in this state.

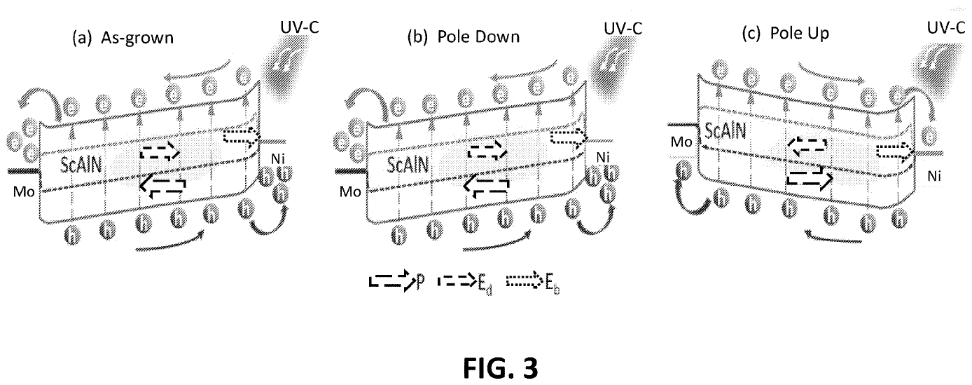

To gain insight into the working mechanism of such a reconfigurable photovoltaic response of the fabricated photodetectors, the photovoltaic process was investigated with the help of energy band diagrams. The bulk ScAlN layer has been considered intrinsic and the work function of the two contacts Ni and Mo are taken as 5.15 eV and 4.6 eV, respectively. Even though a small barrier may be formed at the ScAlN/Mo interface, the barrier height is negligible in comparison to that at the ScAlN/Ni interface to have any significant effect on the carrier collection. As indicated in FIG. 3, two main driving forces responsible for the separation of the photogenerated carriers are: (i) the depolarization field (E_{d}) and (ii) the built-in electric field at the ScAlN/Ni interface (E_{b}). As the polarization direction is similar for the as-grown and the downward poled state, the observed photocurrent is comparable, both in magnitude and direction, in these two states. The electric field arising due to the Schottky barrier at the ScAlN/Ni interface (E_{b}) is in the same direction as the depolarization field, thus they add up resulting in a net field at the interface given by, Eᵢₙₜ=E_{d}+E_{b}. In contrast, when a positive bias is applied to the bottom electrode, the depolarization field gets reoriented in the opposite direction. As a result, the two fields now oppose each other, i.e., Eᵢₙₜ=E_{d}-E_{b}. However, the observed reversal of photocurrent direction in the upward poled state suggests that the depolarization field plays a larger role in driving the photogenerated carriers than the built-in field at the interface. Owing to the resultant electric field at the interface being reoriented, the electrons drift towards the top Ni electrode. Only a small fraction of the photogenerated carriers having energy larger than the ScAlN/Ni interface barrier height can overcome the Schottky barrier and constitute photocurrent. This explains the observed lowering of magnitude of the photocurrent in the Pole Up state. Additionally, if a thin native oxide on the top surface of ScAlN is considered/present, the oxide barrier may further hinder the collection of photogenerated carriers. However, the overall trend of the carrier transport and the subsequent photovoltaic response remains consistent with the one explained above.

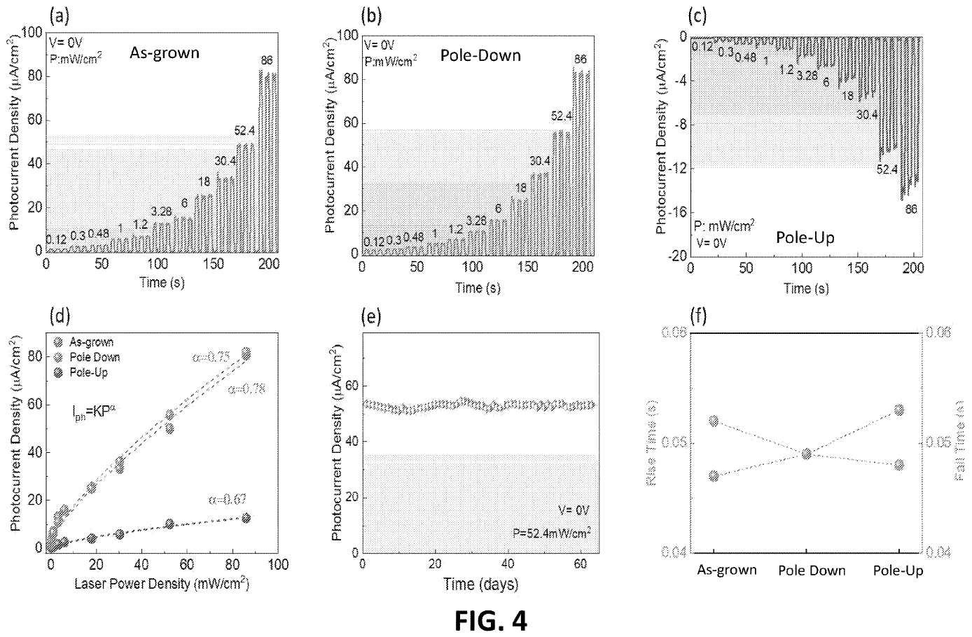

Further characterization of the photo-sensing properties of the example detectors was carried out by pulsed laser measurements, in which the laser is turned ON and OFF at regular intervals with the intensity being regulated by a photo attenuator. To confirm that the photocurrent originates from ferroelectricity induced photovoltaic response of the material, the photocurrent was measured by flipping the connections. Opposite current signals of the same magnitude were observed by reversing the external circuitry, thus corroborating that the obtained signals are true photovoltaic response of the example ScAlN-based photodetector. FIGS. 4, parts a-c, show the light intensity dependent photocurrent characteristics measured for the as-grown, pole-down and pole-up states. For the as-grown and pole-down states, distinguishable photocurrent pulses were observed for an illumination intensity as low as 0.12 mW/cm². For the pole-up state, however, such distinct photocurrent signals were measured only up to an intensity of 0.3 mW/cm² owing to the reduced carrier collection efficiency at the Ni electrode, as explained in connection with FIG. 3.

The irradiation of the active ScAlN layer with higher than band-gap energy photons results in the generation of e-h pairs by photon absorption. At the same time, these carriers are separated by the internal fields and travel along the polarization direction towards the electrodes, resulting in photocurrent even at zero applied bias. Therefore, this photo-induced charge carrier generation is proportional to the absorbed photon flux, i.e., the photocurrent increases with increasing illumination intensity, as can be observed in the laser pulse intensity dependent photo-response cycles (FIG. 4, parts a-c). This relationship can be approximated by a Power Law curve given by Iₚₕ=κP^{α}, where Iₚₕ is the photocurrent density, P is the laser power density and α is the dimensionless exponential constant indicative of the efficiency of separation of the photo-generated carriers. Upon fitting the three curves for the as-grown, pole-down and pole-up states (as shown in FIG. 4, part d), it is observed that both the pole-down and as-grown states have a high value of a greater than or equal to 0.75. This is in accordance with the enhanced photovoltaic response observed in these two states. Nevertheless, a greater than 0.6 is obtained for all three cases, suggesting that traps do not play a dominating role in suppressing the photovoltaic performance of the material.

The stability of the fabricated devices was also analyzed under ambient conditions. As shown in FIG. 4, part e, the photo-response of the devices to deep UV illumination show excellent stability under ambient lighting conditions for more than 60 days without any degradation, with projected lifetime exceeding tens of years. This highly stable photo response is a significant improvement from previously reported ferroelectric self-powered photodetectors based on perovskites, which suffered from performance deterioration only after three weeks.

To investigate the switching speed of photodetectors, individual ON-OFF cycles of the pulsed measurements were implemented. The rise and fall time of the fabricated photodetectors were calculated from the photo-response cycles for each of the three states as shown in FIG. 4, part f. The rise time, defined as the time from 10% to 90% of the peak current value as laser is turned on (τᵣᵢₛₑ) and fall time, defined as the time from 90% to 10% of the peak current value as laser is turned off (τ_{fall}), for all the three states was extracted to be less than 0.06 s. For most ferroelectric based photodetectors, the response time is usually large due to the weak polarization, causing inefficient carrier separation and the presence of recombination centers. In contrast, the fast photo response of the disclosed devices can be attributed to the excellent material quality and strong polarization of the epitaxially grown ferroelectric ScAlN layer.

The steady state photocurrent at varying laser intensities were recorded to calculate the Responsivity (Rₚ) and Detectivity (D*). Responsivity reflects the ability of the photodetector to respond to the incoming light signal and can be calculated as,

$$R = \frac{{I}_{p h}}{P \cdot S} ,$$

where Iₚₕ=I_{light}−I_{dark}. I_{light} and/dark are the currents in the laser ON and OFF states, respectively, P is the laser power density and S is the active area under illumination. Meanwhile, detectivity (D*) measures the ability of the device to successfully distinguish an input signal from the ambient noise, and is given by

$${D}^{*} = \frac{R}{\sqrt{2 {eI}_{dark} S}} .$$

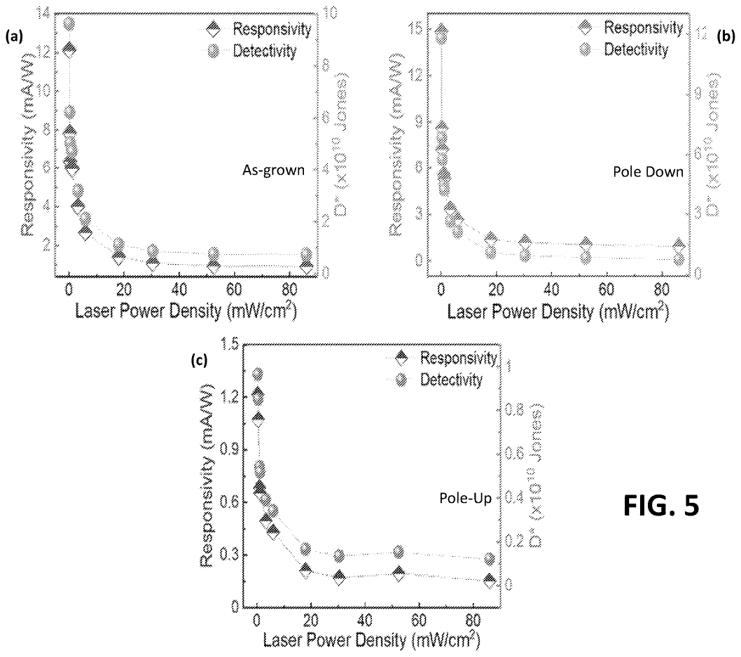

For the disclosed photodetectors, I_{dark} was measured to be about 10 pA. FIGS. 5, parts a-c, show the responsivity and detectivity of the example in the three states. Compared with the as-grown state (Rₘₐₓ=12 mA W⁻¹), the Pole Down state shows almost similar responsivity (Rₘₐₓ=15 mA W⁻¹), whereas the responsivity in the Pole Up state is one order of magnitude lower (Rₘₐₓ=1.2 mA W⁻¹). A similar trend was observed for the detectivity values among the three states, with the as grown and Pole Down states showing the highest specific detectivity of D*=9.6×10¹⁰ Jones and 1.2×10¹¹ Jones, respectively. The minute difference in performance metrics observed between the as-grown and Pole Down state is well within the limits of calculation error, hence the device performance in these two states can be considered identical. It is observed that both Rₚ and D* saturate at higher illumination densities, indicative of increased scattering due to self-heating.

Upon illumination with light sources of different wavelengths (365 nm (UV-A) and 425 nm (visible)), the devices exhibit excellent rejection ratios: R_{193 nm}/R_{365 nm}=34.4 and R_{193 nm}/R_{425 nm}= 48. Also, under ambient lighting conditions, the photocurrent remained similar to the dark current. This suggests that the wide band gap of the active material (e.g., ScAlN) is effective in achieving solar blind UV photodetection as compared to perovskite ferroelectrics, which typically have a narrow band gap.

The table below provides a comparison of device performance parameters of our device with recently reported ferroelectric self-powered UV photodetectors.

| | E_{g} | λ | Rₚ | D* | [symbol] |
|---|---|---|---|---|---|
| Device Structure | (eV) | (nm) | [A/W⁻¹] | [Jones] | [s] |
| Ag/BFO/ITO | 2.8 | 365 | 6.56 × 10 [symbol] | 5.13 × 10 [symbol] | — |
| ITO/BFO/Ag | 2.67 | 365 | 6.0 × 10⁻⁴ | 1 × 10 [symbol] | 10.8/0.6 |
| ITO/NiO/PLZT/FTO | 3.49/3.65 | 350 | 6.3 × 10⁻⁴ | 1.29 × 10¹⁰ | 0.34/0.36 |
| Au/ZnO/PLZT/FTO | 3.22/3.64 | 360 | 3.96 × 10 [symbol] | 6.6 × 10¹⁰ | 0.04/0.05 |
| ITO/BTO/Ag | 3.3 | 405 | 2 × 10 [symbol] | 4 × 10 [symbol] | 0.4/1.6 |
| Ag/BTO/Ag | 3.3 | 365 | 6.1 × 10⁻⁸ | 9.8 × 10 [symbol] | 0.5/23 |
| Au/BFO/Pt | 2.75 | 340 | 2.4 × 10 [symbol] | 2.2 × 10¹⁰ | 0.41 ( [symbol] ) |
| 2D-PMA₂PbCl₄ MMB | 3.63 | 320 | 9 | 1.01 × 10¹¹ | 1.62 × 10 [symbol] /2.26 × [symbol] |
| Ni/ScAIN/Mo* | 5.42 | 193 | 0.015 | 1.2 × 10¹¹ | 0.049/0.049 |

*present work [symbol]
indicates data missing or illegible when filed

The table above provides a detailed comparison of the figure of merits of an example ScAlN-based photodetector with those reported in the literature. The high value of responsivity to deep UV illumination (Rₘₐₓ=15 mA/W), combined with a high rejection ratio to other wavelength illumination suggests that efficient self-powered solar blind deep UV photodetection, which outweighs most of the state-of-the-art ferroelectric photodetectors, was achieved using MBE-grown ferroelectric ScAlN films. The epitaxial growth with atomically precise control inside an ultrahigh vacuum MBE chamber results in much less defects and dislocations than solution processed materials, leading to very low dark current. This is reflected in the photo sensitivity to weak deep UV illumination (as low as about 0.12 mW/cm²) with high detectivity (D*=1.2×10¹¹ Jones) and fast switching response time (τᵣᵢₛₑ/τ_{fall}<0.06 s), which is also comparable to other p-n diode-based photodetectors operating in the UV spectrum. Furthermore, owing to the epitaxial growth in MBE, the crystal orientation is well aligned within the film even without poling, enabling ready-to-use (poling-free) photodetection with excellent stability over 60 days. Overall, the excellent quality of MBE grown ferroelectric material combined with a well-designed device architecture facilitates the development of high performance solar blind ferroelectric photodetectors based on III-nitride alloys such as Sc-III-nitride alloys.

Based on the III-nitride alloys described herein, a wide variety of ferroelectric III-nitride-based optoelectronic devices may be fabricated. For instance, the optoelectronic devices may combine light/piezo-force sensing and nonvolatile reconfigurability for the realization of multi-functional sensors, e.g., with pre-processing capability for efficient human-computer interactions.

Described above are examples of high performance ferroelectric self-powered deep UV-photodetectors based on epitaxially grown ScAlN thin films. The flipping of the polarization of zero-bias photocurrent by an appropriate “writing” voltage confirms the polarization dependent photovoltaic response of the ScAlN based photodetector to deep UV illumination. The devices exhibit wake-up free behavior, fast response times (less than 0.06 s), low dark current (about 10 pA) and extremely stable operation under ambient conditions. The highest specific detectivity (D*=1.2×10¹¹ Jones) and responsivity (Rₘₐₓ=15 mA/W) are recorded at an extremely low illumination intensity of 0.12 mW/cm². Furthermore, the wide-band gap of the nitride ferroelectric results in high rejection ratios to other wavelength illumination, thus making it possible to achieve efficient solar blind deep UV photodetection. In these ways, the ferroelectricity in III-nitride alloys may address the ever escalating interest in developing energy efficient optoelectronic devices and ferroelectric self-powered photodetector systems.

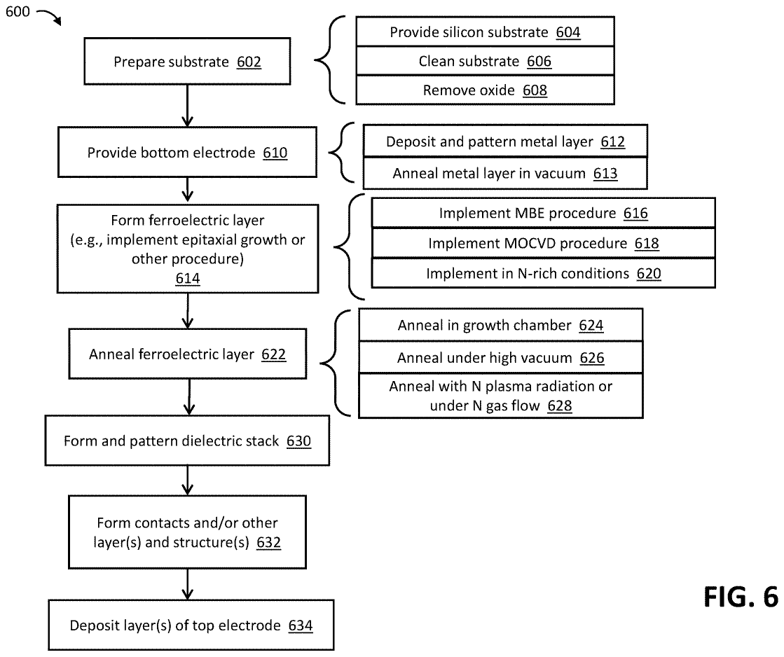

FIG. 6 depicts a method 600 of fabricating an optoelectronic device having a ferroelectric semiconductor layer in accordance with one example. As described herein, the method 600 is configured such that a heterostructure having a wurtzite structure of a III-nitride alloy is achieved. The heterostructure may form a photodetector, such as a deep UV photodetector.

The method 600 may begin with an act 602 in which a substrate is prepared and/or otherwise provided. In some cases, the act 602 includes providing a silicon substrate in an act 604. Alternative or additional substrate materials may be used, including, for instance, sapphire, bulk GaN, bulk AlN, or other semiconductor material. Still other materials may be used, including, for instance, silicon carbide. The substrate may be cleaned in an act 606. In some cases, a native or other oxide layer may be removed from a substrate surface in an act 608. Additional or alternative procedures may be implemented, including, for instance, a nitridation procedure, doping, and/or deposition procedures. The substrate thus may or may not have a uniform composition. The substrate may be a uniform or composite structure.

In an act 610, a bottom electrode is formed or otherwise provided. The bottom electrode may thus be formed on, or otherwise supported by, the substrate. The bottom electrode may or may not be in contact with the substrate. The bottom electrode may be composed of, or otherwise include, a metal layer, such as Mo. Alternative or additional metals may be deposited. For example, an aluminum layer may be deposited on a silicon substrate in preparation for the epitaxial growth of the wurtzite structure. The characteristics of the bottom electrode may vary in other ways. For instance, in some cases, the bottom electrode may constitute or include a bulk metal or a semiconductor substrate.

The act 610 may include an act 612 in which the metal layer(s) is/are deposited and an act 613 in which a surface treatment procedure is implemented (e.g., to remove oxide from a surface of the metal layer). In some cases, the act 613 includes annealing the metal layer in a vacuum. The temperature of the annealing may vary, e.g., with the composition of the metal layer. For instance, MoO₃ has a relatively low melting point (795° C.), in which case annealing above the melting point, e.g., at about 900° C., may be used.

The annealing may also improve the surface roughness of the metal layer. In one example involving annealing at 900° C. for 10 minutes, except for the domain boundaries, a smooth surface may be achieved on each domain. Furthermore, after the high-temperature annealing, the domain boundaries may be more uniform with significantly reduced misoriented clusters. The oxide may be removed in additional or alternative ways to achieve a highly ordered atomically smooth surface. For instance, the oxide may be removed via an etching procedure using, e.g., an acid solution, such as hydrochloric acid (HCl) or buffered hydrofluoric acid (BHF).

In one example, a 120-nm-thick Mo layer was grown on a Si (111) substrate. The Mo template was cleaned by acetone, methanol, and deionized water prior to loading into the MBE system used for the growth of the single-crystalline semiconductor layer. The Mo templates were then degassed at 200 and 600° C. for 2 h in the MBE load-lock chamber and preparation chamber, respectively. In the growth chamber, the Mo template was annealed at 900° C. for 10 min before starting ScAlN growth, but the temperature and other parameters may vary in other cases (e.g., in connection with the composition).

In an act 614, a non-sputtered epitaxial growth procedure is implemented at a growth temperature to form a wurtzite structure supported by the bottom electrode. As described herein, the wurtzite structure is composed of, or otherwise includes, an alloy of a III-nitride material. For instance, the III-nitride material may be AlN. Additional or alternative III-nitride materials may be used, including, for instance, gallium nitride (GaN), indium nitride (InN), and their alloys. As also described herein, the epitaxial growth procedure is configured to incorporate scandium and/or another group IIIB element into the alloy of the III-nitride material. The alloy may thus be ScₓAl₁₋ₓN, for example. In some cases, the act 614 includes an act 616 in which an MBE procedure is implemented. In other cases, an MOCVD or other non-sputtered epitaxial growth procedure is implemented in an act 618.

The surface treatment of the act 613 may be implemented before (e.g., in preparation for) implementing the epitaxial growth procedure in which a wurtzite structure is formed. The wurtzite structure may thus be formed on the metal layer. The metal layer may thus act as a template for the wurtzite structure and/or other elements of the heterostructure.

In some cases, the act 614 may include growing the single-crystalline semiconductor layer in a chamber in which the annealing procedure for the surface treatment of the act 613 is implemented. As a result, the substrate may remain within, e.g., is not removed from, the epitaxial growth chamber between forming the metal layer and growing the single-crystalline semiconductor layer. Thus, sequential layers of the heterostructure may thus be grown without exposure to the ambient. The quality of the interface between the layers may accordingly be improved.

The single-crystalline semiconductor layer may be grown on the metal layer using a wide growth window. For example, in some cases, the growth window may be similar to that for ScAlN grown on GaN, in which the low end of the growth temperature window is compatible with a CMOS fabrication process.

The growth temperature may be at a level such that the wurtzite structure exhibits a breakdown field strength greater than a ferroelectric coercive field strength of the wurtzite structure. Ferroelectric switching and other ferroelectric behavior may thus be achieved.

The growth temperature may be at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single-crystalline scandium-including alloy (e.g., a monocrystalline layer of the alloy) at the growth temperature level may nonetheless be achieved. For example, in some cases, a ScAlN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius or lower would result in structures of such poor quality. In contrast, the epitaxially grown ScAlN layer grown at that low temperature is unexpectedly of high quality and good electrical properties.

Growth of the ScAlN layer at the conventional AlN growth temperature (and other temperatures above the upper bound) unexpectedly results in the formation of dislocations and/or other leakage paths in the ScAlN layer. With the leakage paths, the ScAlN layer has a breakdown field strength level too low (e.g., below the ferroelectric coercive field strength level). The layer accordingly does not exhibit ferroelectric behavior.

In some cases, the growth temperature may be about 650 degrees Celsius or less. The growth temperature may correspond with the temperature measured at a thermocouple in the growth chamber. The growth temperature at the epitaxial surface may be slightly different. The growth temperature is accordingly approximated via the temperature measurement at the thermocouple.

The upper bound of the growth temperature range may vary in accordance with the alloy and/or the epitaxial growth technique. For instance, in other cases, the upper bound on the growth temperature may be higher, such as about 700 degrees Celsius, or about 750 degrees Celsius. In still other cases, the upper bound may be lower, including, for instance, about 550 degrees Celsius or about 600 degrees Celsius.

At each level within the above-described ranges of suitable growth temperatures, the resulting wurtzite structure is monocrystalline. The resulting wurtzite structure is monocrystalline to a degree not realizable via, for instance, sputtering-based procedures for forming ScAlN layers. Such procedures are only capable of producing structures with x-ray diffraction rocking curve line widths on the order of a few degrees at best. In contrast, the structures grown by the disclosed methods exhibit x-ray diffraction rocking curve line widths on the order of a few hundred arc-seconds or less, well over an order of magnitude less. In this manner, leakage current paths are minimized or otherwise sufficiently reduced so that the resulting wurtzite structure has a suitably high breakdown field strength level, e.g., sufficiently greater than the ferroelectric coercive field strength.

Additional or alternative differences in crystal quality may be used to distinguish between single-crystalline (or monocrystalline) and polycrystalline structures. As used herein, the term “polycrystalline” refers to structures having multiple domains with in-plane rotation. As used herein, the terms “monocrystalline” or “single crystalline” refer to structures having unique domains without in-plane rotation, e.g., as indicated by x-ray φ scans that have only one set of diffraction peaks.

Comparing the wurtzite structures of the layers grown by MBE or other non-sputtered techniques (e.g., MOCVD or HVPE) with sputtering deposition techniques, the microstructure of the former techniques is more uniform with highly ordered stacking sequence of atoms. In sputter deposited layers, domains with cubic phase or domains with in-plane mis-orientation are readily observed. The existence of these mis-aligned domains suppresses the complete switching of polarization, and further results in the fast loss of polarization during fatigue testing. Regarding phase purity, the highly crystallographic orientation of layers grown by MBE or other non-sputtered techniques exhibits more repeatable ferroelectric switching, which is useful in a number of device applications.

In some cases, the wurtzite structure of the single-crystalline semiconductor layer is metal-polar. In other cases, the single-crystalline semiconductor may be nitrogen-polar (N-polar).

In some cases, the epitaxial growth procedure is implemented under a nitrogen-rich condition. For example, the nitrogen-to-metal flux ratio may be set in an act 620 in which the nitrogen flow is controlled. In some cases, the unbalanced flux ratio may be set to a highly or extremely nitrogen (N)-rich condition, such as a N-to-metal flux ratio of 2-to-1 or higher.

Control of the flux ratio between metal and nitrogen sources may be useful for improving the material quality of the ScAlN or other III-nitride alloy layer. As described herein, the N-rich growth conditions may be useful in connection with the growth of ScAlN to avoid Sc—Al intermetallic, Sc₃AlN perovskite phase formation, and/or other defects.

The growth temperature may be at a level such that the wurtzite structure exhibits a breakdown field strength greater than a ferroelectric coercive field strength of the wurtzite structure. Ferroelectric switching and other behavior may thus be achieved.

The growth temperature is at a level lower than what would be expected given the III-nitride material. In some examples, the growth temperature level is significantly less than the temperature at which the III-nitride material would typically be grown. For instance, the growth temperature level may be such that attempts to grow a structure composed of the III-nitride material (i.e., without scandium) at the growth temperature level would not be worthwhile. The resulting structure would be of such poor quality (e.g., possess far too many defects) to be useful. Growth of a single crystal of the scandium-including alloy (e.g., a monocrystalline layer of the alloy) at the growth temperature level may nonetheless be achieved. For example, in some cases, a ScₓAl₁₋ₓN alloy may be epitaxially grown at a growth temperature of about 650 degrees Celsius despite that the corresponding (scandium-free) III-nitride material, AlN, is conventionally grown at much higher temperatures, e.g., about 1000 degrees Celsius. Conversely, attempts to grow AlN at about 650 degrees Celsius or lower would result in structures of such poor quality so as to be useless. In contrast, the epitaxially grown ScₓAl₁₋ₓN layer grown at that low temperature is unexpectedly monocrystalline and of high quality.

Growth of the ScₓAl₁₋ₓN layer at the conventional AlN growth temperature (and other temperatures above the upper bound) unexpectedly results in the formation of dislocations and/or other leakage paths in the ScₓAl₁₋ₓN layer. With the leakage paths, the ScₓAl₁₋ₓN layer has a breakdown field strength level too low (e.g., below the ferroelectric coercive field strength level). The layer accordingly does not exhibit ferroelectric behavior.

The above-noted differences in crystal quality evidenced via x-ray diffraction rocking curve line widths may also be used to distinguish between monocrystalline and polycrystalline structures. For instance, as used herein, the term “polycrystalline” refers to structures having x-ray diffraction rocking curve line widths on the order of a few degrees or higher. As used herein, the term “monocrystalline” refers to structures having x-ray diffraction rocking curve line widths at least one order of magnitude lower than the order of a few degrees.

The wurtzite structure may then be annealed in an act 622. The annealing may be implemented at a temperature greater than the growth temperature. In some cases, the annealing temperature falls in a range from about 700 Celsius to about 1500 degrees Celsius. Examples of films prepared with such annealing exhibited stable polarization switching with further reduced leakage current relative to non-annealed films. Film or device uniformity was also improved via the annealing, thereby further improving the polarization switching behavior of the ferroelectric Sc-III-N alloys. The underlying mechanism for the improved performance and uniformity with annealing is attributed to the reduced threading dislocation density and defect density, which usually act as electric leakage paths. Such usefulness of the post-growth annealing is realized despite past concerns that high processing temperatures can lead to a loss of ferroelectricity.

Such post-growth high-temperature annealing of ScₓAl₁₋ₓN may be performed in-situ in the same growth chamber (e.g., the same MBE chamber) in an act 624. In other cases, the annealing is performed ex-situ in a chamber directed to annealing procedures.

The annealing process may be implemented under high vacuum in an act 626 (e.g., in-situ in the growth chamber). In other cases, the annealing may be implemented either with nitrogen plasma radiation or under nitrogen gas flow in an act 628.

The above-described annealing procedure may be implemented in connection with films grown under any of the above-described growth conditions. For instance, the annealing procedure may be implemented after growth under slightly to moderately N-rich conditions at a growth temperature below about 650 degrees Celsius. The annealing procedure may also be implemented after growth under unbalanced flux ratios (e.g., N-rich or extreme N-rich conditions) at growth temperatures above about 650 degrees Celsius.

The method 600 may include an act 630 in which one or more dielectric layers (e.g., of a dielectric stack) are formed after growth of the wurtzite structure. As a result, the layer(s) may be in contact with the wurtzite structure. In some examples, layers of SiO₂ and HfO₂ are formed. Additional, alternative or fewer dielectric layers may be included. The components, composition, thicknesses, and other characteristics of the dielectric stack may thus vary. The act 630 may be implemented in the same epitaxial growth chamber used to grow the wurtzite structure. As a result, the heterostructure may not be removed from the epitaxial growth chamber between implementation of the act 614 and the act 630. The act 630 may include one or more procedures directed to patterning the dielectric stack, e.g., to define active areas of the device. Additional or alternative techniques for defining the active area(s) of the device may be used.

Contacts and/or other conductive layers or structures may then be formed in an act 632. As described above, the act 632 may include the deposition and patterning of one or more metal layers, including, for instance, titanium and gold layers. The act 632 may be directed to forming contacts for one or both of the bottom and top electrodes.

The method 600 includes an act 634 in which a top electrode is formed. One or more metal or other conductive layers or structures may be deposited. The top electrode may include a UV-transparent nickel layer, as described above. The top electrode may include one or more additional or alternative metal layers, including, for instance, one or more contact metal layers.

The method 600 may include one or more additional acts. For example, one or more acts may be directed to patterning the heterostructure to define an area for the bottom contact, as described above.

The order of the acts of the method 600 may differ from the example shown in FIG. 6. For example, the acts directed to forming electrodes, contacts and/or other conductive structures (e.g., the acts 632, 634) may be implemented in a different order and/or at different stages of the process.

Described above are examples of devices exhibiting efficient photoelectric conversion based on the ferroelectric property of a III-nitride alloy. The electrically reconfigurable photovoltaic effect of the disclosed devices provides self-powered ultraviolet (UV) photodetectors for a broad range of applications from the military to human health and the environment. The disclosed devices avoid the low performance metrics of past photodetectors that have hindered their integration with existing platforms. The unique optoelectronic properties of an ultrawide bandgap nitride ferroelectric material (e.g., ScAlN) support the realization of polarization dependent high-performance self-powered deep UV photodetectors. The responsivity at 193 nm illumination reached up to a maximum of 15 mA/W with a detectivity of 1.2×10¹¹ Jones at an extremely low illumination intensity of 0.12 mW/cm². Furthermore, the photodetectors exhibit wake-up free and reconfigurable photo-response, fast and stable switching response time (<0.06 s) with excellent rejection to UV-A and visible illumination. The growth, fabrication and characterization of the disclosed devices enable the realization of unprecedentedly high performance self-powered ferroelectric UV photodetectors useful in energy-efficient and other applications.

The term “about” is used herein in a manner to include deviations from a specified value that would be understood by one of ordinary skill in the art to effectively be the same as the specified value due to, for instance, the absence of appreciable, detectable, or otherwise effective difference in operation, outcome, characteristic, or other aspect of the disclosed methods and devices.

The present disclosure has been described with reference to specific examples that are intended to be illustrative only and not to be limiting of the disclosure. Changes, additions and/or deletions may be made to the examples without departing from the spirit and scope of the disclosure.

The foregoing description is given for clearness of understanding only, and no unnecessary limitations should be understood therefrom.

What is claimed is:

1. An optoelectronic device comprising:
a first electrode;
a ferroelectric semiconductor layer supported by the first electrode; and
a second electrode supported by the ferroelectric semiconductor layer, the second electrode being configured to allow the ferroelectric semiconductor layer to be illuminated;
wherein the ferroelectric semiconductor layer comprises a III-nitride alloy, the III-nitride alloy comprising a group IIIB element.

2. The optoelectronic device of claim 1, wherein the III-nitride alloy has a bandgap sufficiently wide such that the optoelectronic device is solar-blind.

3. The optoelectronic device of claim 1, wherein the III-nitride alloy has a bandgap that corresponds with an ultraviolet C (UV-C) wavelength.

4. The optoelectronic device of claim 1, wherein the ferroelectric semiconductor layer is in contact with the first electrode.

5. The optoelectronic device of claim 1, wherein an interface between the first electrode and the ferroelectric semiconductor layer is buffer-free.

6. The optoelectronic device of claim 1, wherein the ferroelectric semiconductor layer exhibits uniform polarity.

7. The optoelectronic device of claim 1, wherein the first electrode comprises molybdenum.

8. The optoelectronic device of claim 1, wherein the first electrode comprises a bulk metal.

9. The optoelectronic device of claim 1, wherein the first electrode comprises a semiconductor substrate.

10. The optoelectronic device of claim 1, wherein the first electrode comprises a substrate and a metal layer supported by the substrate.

11. The optoelectronic device of claim 1, wherein the group IIIB element is scandium.

12. The optoelectronic device of claim 1, wherein the III-nitride alloy is ScAlN.

13. A method of fabricating an optoelectronic device, the method comprising:
providing a first electrode;
implementing a non-sputtered, epitaxial growth procedure to form a ferroelectric semiconductor layer supported by the first electrode; and
depositing a second electrode across the ferroelectric semiconductor layer, the second electrode being configured to allow the ferroelectric semiconductor layer to be illuminated;
wherein the ferroelectric semiconductor layer comprises a III-nitride alloy, the III-nitride alloy comprising a group IIIB element.

14. The method of claim 13, wherein the non-sputtered, epitaxial growth procedure is implemented in N-rich conditions.

15. The method of claim 13, wherein providing the first electrode comprises forming a metal layer on a substrate.

16. The method of claim 15, wherein the metal layer comprises molybdenum.

17. The method of claim 15, wherein forming the metal layer comprises removing an oxide from a surface of the metal layer.

18. The method of claim 15, wherein forming the metal layer comprises annealing the metal layer in a vacuum to remove an oxide from a surface of the metal layer.

19. The method of claim 13, wherein the first electrode comprises a bulk metal.

20. The method of claim 13, wherein the first electrode comprises a semiconductor substrate.

21. The method of claim 13, wherein implementing the non-sputtered, epitaxial growth procedure comprises growing the ferroelectric semiconductor layer on the first electrode such that an interface between the first electrode and the ferroelectric semiconductor layer is buffer-free.

22. The method of claim 13, further comprising annealing the ferroelectric semiconductor layer.

23. The method of claim 13, wherein the III-nitride alloy is ScAlN.
